(19) United States
(12) Patent Application Publication
(10) Pub. No.: US 2016/0372667 A1
(43) Pub. Date: Dec. 22, 2016

(54) LIGHT EMITTING COMPOSITION AND DEVICE

(71) Applicants: Cambridge Display Technology Limited, Godmanchester (GB); Sumitomo Chemical Company Limited, Tokyo (JP)

(72) Inventors: Thomas Kugler, Cambridge (GB); William Tarran, Godmanchester (GB)

(73) Assignees: Cambridge Display Technology Limited, Godmanchester (GB); Sumitomo Chemical Company, Tokyo (JP)

(21) Appl. No.: 15/181,686

(22) Filed: Jun. 14, 2016

(30) Foreign Application Priority Data
Jun. 19, 2015 (GB) 1510862.4

(51) Int. Cl. H01L 51/00; C09K 11/02; C09K 11/06; H01L 51/56

(52) U.S. Cl. CPC H01L 51/006; H01L 51/56; H01L 51/0085; H01L 51/0043; H01L 51/0039; C09K 11/025; C09K 11/06; H01L 51/5016

(57) ABSTRACT

An organic light-emitting device comprising an anode; a cathode; and a first light- emitting layer between the anode and the cathode, wherein the first light-emitting layer comprises a fluorescent light-emitting material of formula (I):

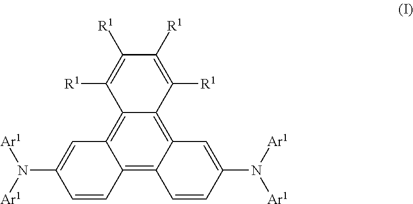

wherein Ar¹ independently in each occurrence is a substituted or unsubstituted aryl or heteroaryl group and each R¹ is independently H or a substituent; and wherein a first phosphorescent light-emitting material is provided in the first light-emitting layer or in a second light-emitting layer adjacent to the first light-emitting layer.

### Related Applications

This application claims the benefits under 35 U.S.C. §119(a)-(5 d) or 35 U.S.C. §365(b) of British application number GB 1510862.4, filed Jun. 19, 2015, the entirety of which is incorporated herein.

### FIELD OF THE INVENTION

The present invention relates to organic light-emitting devices and compositions, and methods of forming such organic light-emitting devices.

### BACKGROUND

Electronic devices comprising active organic materials are attracting increasing attention for use in devices such as organic light emitting diodes, organic photoresponsive devices (in particular organic photovoltaic devices and organic photosensors), organic transistors and memory array devices. Devices comprising organic materials offer benefits such as low weight, low power consumption and flexibility. Moreover, use of soluble organic materials allows use of solution processing in device manufacture, for example inkjet printing or spin-coating.

An organic light-emitting device (OLED) may comprise a substrate carrying an anode, a cathode and an organic light-emitting layer between the anode and cathode comprising a light-emitting material. Further layers may be provided between the anode and the cathode, for example one or more charge-injection or charge-transport layers.

During operation of the device, holes are injected into the device through the anode and electrons are injected through the cathode. Holes in the highest occupied molecular orbital (HOMO) and electrons in the lowest unoccupied molecular orbital (LUMO) of the light-emitting material combine in the light-emitting layer to form an exciton that releases its energy as light.

Suitable light-emitting materials include small molecule, polymeric and dendrimeric materials. Suitable light-emitting polymers for use in the light-emitting layer include poly(arylene vinylenes) such as poly(p-phenylene vinylenes) and polyarylenes such as polyfluorenes.

The light emitting layer may contain a semiconducting host material and a light-emitting dopant wherein energy is transferred from the host material to the light-emitting dopant. For example, J. Appl. Phys. 65, 3610, 1989 discloses a host material doped with a fluorescent light-emitting dopant (that is, a light-emitting material in which light is emitted via decay of a singlet exciton) and Appl. Phys. Lett., 2000, 77, 904 discloses a host material doped with a phosphorescent light emitting dopant (that is, a light-emitting material in which light is emitted via decay of a triplet exciton).

Hosts for luminescent dopants include “small molecule” materials such as tris-(8-hydroxyquinoline) aluminium (“Alq3”) and non-conjugated polymers such as polyvinylcarbazole (“PVK”).

In order to function effectively as a host it is necessary for the relevant excited state energy level of the host material to be sufficiently high to allow transfer of excitons from an excited state energy level of the host to an excited state energy level of a luminescent dopant (for example, transfer to the singlet excited state energy level S₁ for a fluorescent emitter and the triplet excited state energy level T₁ for a phosphorescent emitter).

It may be desirable to provide multiple light-emitting materials in the same light-emitting layer or in adjacent layers, for example to obtain white light, however singlet and/or triplet excitons may transfer to the material or materials with the lowest excited state energy, resulting in quenching of emission from one or more materials with a higher excited state energy.

Schwartz et al, “Triplet Harvesting in Hybrid White Organic Light-Emitting Diodes”, Adv. Funct. Mater. 2009, 19, 1319-1333, discloses use of a blue fluorophor with red and green phosphors in both separate fluorescent and phosphorescent layer and in a “triple blend” layer containing the blue fluorescent emitter and the green and red phosphorescent emitters. In the case of the “triple blend” layer device, doping of the green phosphorescent emitter Ir(ppy)₃ into fluorescent blue emitter 4P-NPD is reported to result in a complete lack of green emission, which is attributed to triplet exciton transfer from the green phosphorescent emitter to the blue emitter.

U.S. Pat. No. 7,977,862 discloses a white OLED having a light-emitting region comprising a layer of fluorescent blue electroluminescent material doped with one or more phosphorescent materials that emit red light or green light.

U.S. Pat. No. 7,863,812 discloses a white light emitting OLED having a single layer comprising a blue-to-green host material and red-to-yellow dopant.

U.S. Pat. No. 7,830,085 discloses a white OLED having an emissive layer comprising a conjugated semiconducting polymer capable of fluorescent emission serving as a host to at least one admixed phosphorescent emitter.

US 2014/252339 discloses an OLED comprising a fluorescent light-emitting material in a first light-emitting layer and a phosphorescent light-emitting material in the first light-emitting layer or in an adjacent second light-emitting layer.

It is an object of the invention to provide a device containing both fluorescent and phosphorescent emitters wherein quenching of phosphorescent emission is limited or avoided. It is a further object of the invention to provide a device containing both fluorescent and phosphorescent light-emitting materials, in particular fluorescent blue and phosphorescent green light-emitting materials, wherein these two emitters are provided in the same layer or in adjacent layers and wherein quenching of phosphorescence is limited or avoided.

### SUMMARY OF THE INVENTION

In a first aspect the invention provides an organic light-emitting device comprising an anode; a cathode; and a first light-emitting layer between the anode and the cathode, wherein the first light-emitting layer comprises a fluorescent light-emitting material of formula (I):

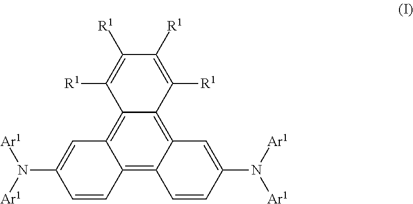

wherein Ar¹ independently in each occurrence is a substituted or unsubstituted aryl or heteroaryl group and each R¹ is independently H or a substituent; and wherein a first phosphorescent light-emitting material is provided in the first light-emitting layer or in a second light-emitting layer adjacent to the first light-emitting layer.

In a second aspect, the invention provides a light-emitting composition comprising a fluorescent light-emitting material of formula (I) and a first phosphorescent light-emitting material:

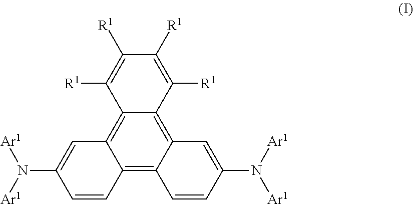

wherein Ar¹ and R¹ are as described in the first aspect.

In a third aspect the invention provides a formulation comprising a composition according to the second aspect and at least one solvent.

In a fourth aspect the invention provides a method of forming an OLED according to the first aspect, the method comprising the steps of forming the first and, if present, the second light-emitting layer over the anode; and forming a cathode over the first and second light-emitting layers, wherein the light-emitting layers may be deposited in any order in the case where the second light-emitting layer is present.

### DESCRIPTION OF THE DRAWINGS

The invention will now be described in more detail with reference to the Figures, in which:

FIG. 1A illustrates an OLED according to an embodiment of the invention;

FIG. 1B illustrates an OLED according to another embodiment of the invention;

FIG. 2 illustrates the electroluminescence spectra of white OLEDs according to embodiments of the invention; and

FIG. 3 illustrates the external quantum efficiencies vs voltage of white OLEDs according to embodiments of the invention.

### DETAILED DESCRIPTION OF THE INVENTION

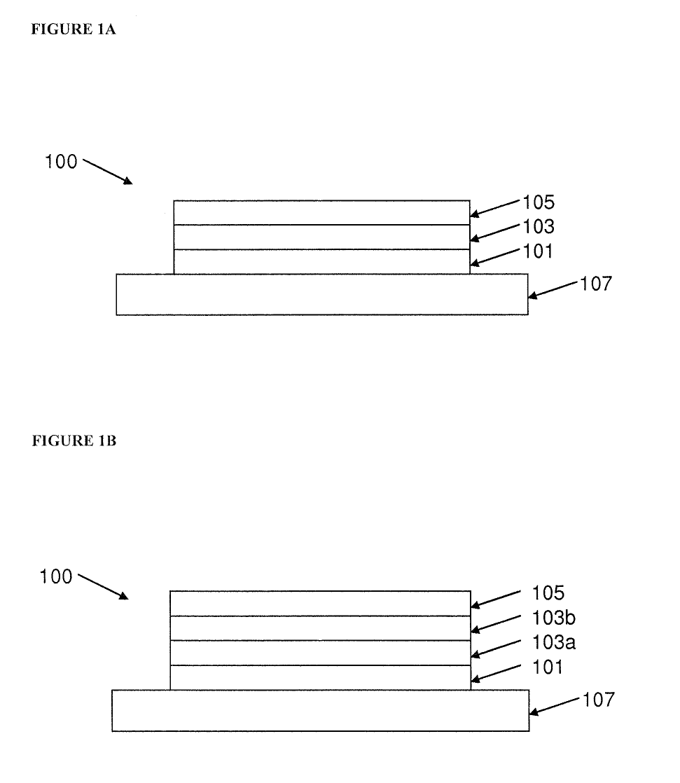

FIG. 1A illustrates an OLED according to an embodiment of the invention. The OLED 100 has an anode 101, a cathode 105 and a light-emitting layer 103 between the anode and the cathode formed on a substrate 107. Further layers may be provided between the anode and the cathode including one or more of a hole injection layer, a hole transporting layer and an electron blocking layer between the anode and the light-emitting layer, and one or more of a hole-blocking layer and an electron-transporting layer between the cathode and the light-emitting layer.

Exemplary OLED structures including one or more further layers include the following:

Anode/Hole-injection layer/Light-emitting layer/Cathode

Anode/Hole transporting layer/Light-emitting layer/Cathode

Anode/Hole-injection layer/Hole-transporting layer/Light-emitting layer/Cathode

Anode/Hole-injection layer/Hole-transporting layer/Light-emitting layer/Electron-transporting layer/Cathode.

Preferably, at least one of a hole-transporting layer and hole injection layer is present.

Preferably, both a hole injection layer and hole-transporting layer are present.

Preferably, an electron-transporting layer is present.

A fluorescent light-emitting material of formula (I) and a first phosphorescent light-emitting material are provided in light-emitting layer 103. The fluorescent light-emitting material of formula (I) is preferably a blue fluorescent light-emitting material and the first phosphorescent light-emitting material may be a green phosphorescent light-emitting material. The layer 103 may contain one or more further light-emitting materials, and in the case of a white light-emitting OLED the layer 103 may contain a second phosphorescent light-emitting material. Preferably, the second phosphorescent material has a lowest triplet excited state (T₁) energy level that is lower than that of the first phosphorescent material. Optionally, the second phosphorescent material is a red phosphorescent material.

The light-emitting layer may further contain a host material. The host material may have a singlet energy level sufficient for transfer of singlet excitons to the fluorescent light-emitting material of formula (I) and/or sufficient for transfer of triplet excitons to the phosphorescent light-emitting material. Preferably, the host material has a lowest excited state energy level (S₁) that is the same as or higher than that of the fluorescent material of formula (I). Preferably, the host material has a lowest triplet excited state energy level (T₁) that is the same as or higher than that of the phosphorescent light-emitting material. The host material may have a T₁ level that is the same as or higher than that of the he fluorescent material of formula (I).

The fluorescent emitter may be provided in an amount in the light-emitting layer in an amount in the range of 1-20 mol %. The first phosphorescent light-emitting material may be provided in an amount in the range of 0.1-5 mol %, optionally 0.1-1 mol % or 0.1-0.5 mol %.

Preferably, the molar amount of the fluorescent light-emitting material of formula (I) is greater than that of the first phosphorescent light-emitting material. Optionally, the fluorescent light-emitting material of formula (I):first phosphorescent light-emitting material molar ratio is less than 20:1, optionally 10:1 or less.

Where two or more phosphorescent materials having different colours are present in light-emitting layer 103, for example a red phosphorescent material and a green phosphorescent material, the concentration of the phosphorescent material having the longest peak photoluminescent wavelength (lowest triplet energy level) may be provided in the light-emitting layer an amount in the range of 0.1-2 mol %, preferably 0.1-1 mol % or 0.1-0.5 mol %.

In the embodiment of FIG. 1A preferably all light emitted from the device in use is emitted from light-emitting layer 103.

A blue light-emitting material as described herein may have a photoluminescence spectrum with a peak of less than 490 nm and optionally greater than 400 nm, optionally in the range 420 nm -less than 490 nm.

A green light-emitting material as described herein may have a photoluminescence spectrum with a peak in the range of 490-580 nm, optionally in the range 490-540 nm.

A red light-emitting material as described herein may have a photoluminescence spectrum with a peak greater than 580 nm, optionally greater than 585 nm, up to 700 nm.

The photoluminescence spectrum of a light-emitting material as described herein may be measured by casting 5 wt % of the material in a PMMA film onto a quartz substrate to achieve transmittance values of 0.3-0.4 and measuring in a nitrogen environment using apparatus C9920-02 supplied by Hamamatsu.

FIG. 1B illustrates an OLED according to a further embodiment of the invention. The device is as described with reference to FIG. 1A, except that the device has two light-emitting layers 103a and 103b between the anode and the cathode. Further layers may be provided between the anode and the cathode, as described with reference to FIG. 1A. Preferably, all light emitted from the device in use is from light-emitting layers 103a and 103b.

The fluorescent light-emitting material of formula (I), the first phosphorescent material and, if present, the second phosphorescent material and any other light-emitting materials may independently be provided in one of layers 103a and 103b, with the proviso that each of layers 103a and 103b contains at least one light-emitting material.

In other embodiments more than two light-emitting layers may be present.

In the case of a white light-emitting OLED, the light emitted may have CIE x coordinate equivalent to that emitted by a black body at a temperature in the range of 2500-9000K and a CIE y coordinate within 0.05 or 0.025 of the CIE y co-ordinate of said light emitted by a black body, optionally a CIE x coordinate equivalent to that emitted by a black body at a temperature in the range of 2700-4500K.

Fluorescent Light-Emitting Material

The compound of formula (I) is preferably a blue light-emitting material.

Ar¹ of the compound of formula (I) is preferably phenyl that may be unsubstituted or substituted with one or more substituents. If present, the or each substituent may independently be selected from C₁₋₂₀ alkyl wherein one or more non-adjacent C atoms may be replaced O, S, C═O or —COO—, and one or more H atoms may be replaced with F.

R¹ of the compound of formula (I) is preferably an aryl group, more preferably phenyl.

Each aryl group R¹ may be unsubstituted or may be substituted with one or more substituents. If present, the or each substituent may independently be selected from C₁₋₂₀ alkyl wherein one or more non-adjacent C atoms may be replaced O, S, C═O or —COO—, and one or more H atoms may be replaced with F.

Optionally, the compound of formula (I) is an unsubstituted or substituted compound of formula:

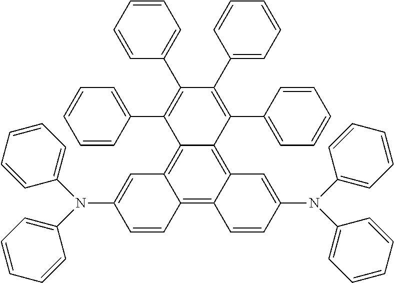 [SMILES: c1ccc(-c2c(-c3ccccc3)c(-c3ccccc3)c3c4cc(N(c5ccccc5)c5ccccc5)ccc4c4ccc(N(c5ccccc5)c5ccccc5)cc4c3c2-c2ccccc2)cc1]

The fluorescent light-emitting material of formula (I) may be covalently bound to a polymer as a repeat unit in the polymer backbone, a side-group pendant from the polymer backbone or an end-group of the polymer, preferably as a polymer side group.

Where present as a side-group, the fluorescent light-emitting material may be bound directly to a repeat unit in the polymer backbone, or spaced apart therefrom by a spacer group. Exemplary spacer groups are hydrocarbyl groups, optionally C₁₋₃₀ hydrocarbyl groups, for example C₁₋₂₀ alkyl and phenyl-C₁₋₂₀ alkyl. One or more non-adjacent C atoms of an alkyl group of a spacer chain may be replaced with O, S, NR¹⁵, C═O and —COO—, wherein R¹⁵ is a substituent, preferably C₁₋₁₀ hydrocarbyl.

Exemplary polymers that the fluorescent light-emitting material may be bound to include conjugated and non-conjugated polymers. The fluorescent material of formula (I) may be bound as a side-group of a repeat unit of a host polymer. Exemplary host polymers are described in more detail below. The compound of formula (I) may be bound to a polymer through any of Ar¹ and R¹.

The triplet energy level of the fluorescent light-emitting material is preferably at least 2. eV, preferably at least 2.5 eV.

The lowest triplet excited state energy level of the fluorescent light-emitting material is preferably no more than 0.1 eV lower than that of the first phosphorescent material, and is preferably the same as or higher than that of the first phosphorescent material.

Triplet energy levels described anywhere herein may be measured from the energy onset of the phosphorescence spectrum measured by low temperature phosphorescence spectroscopy (Y. V. Romaovskii et al, Physical Review Letters, 2000, 85 (5), p 1027, A. van Dijken et al, Journal of the American Chemical Society, 2004, 126, p 7718).

Other examples of fluorescent blue compounds that may be used in combination with a first phosphorescent emitter as described herein include the following:

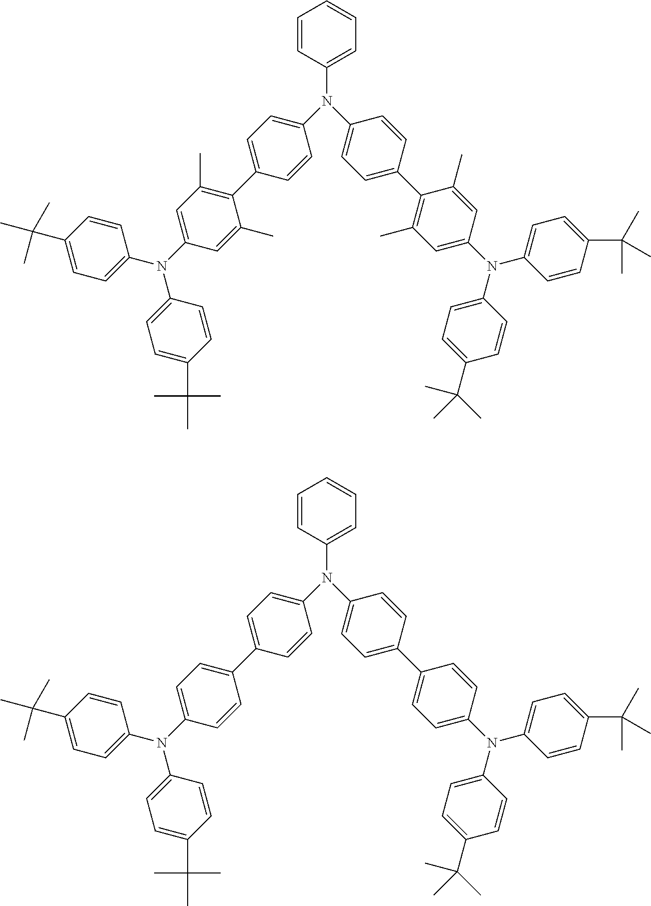

Phosphorescent Light-Emitting Materials

Exemplary phosphorescent compounds have formula (IX):

ML¹_{q}L²ᵣL³ₛ (IX)

wherein M is a metal; each of L¹, L² and L³ is a coordinating group that independently may be unsubstituted or substituted with one or more substituents; q is a positive integer; r and s are each independently 0 or a positive integer; and the sum of (a. q)+(b. r)+(c.s) is equal to the number of coordination sites available on M, wherein a is the number of coordination sites on L¹, b is the number of coordination sites on L² and c is the number of coordination sites on L³.

a, b and c are preferably each independently 1, 2 or 3. Preferably, a, b and c are each a bidentate ligand (a, b and c are each 2). In an embodiment, q is 3 and r and s are 0. In another embodiment, q is 1 or 2, r is 1 and s is 0 or 1.

Heavy elements M induce strong spin-orbit coupling to allow rapid intersystem crossing and emission from triplet or higher states. Suitable heavy metals M include d-block metals, in particular those in rows 2 and 3 i.e. elements 39 to 48 and 72 to 80, in particular ruthenium, rhodium, palladium, rhenium, osmium, iridium, platinum and gold. Iridium is particularly preferred.

Exemplary ligands L¹, L² and L³ include carbon or nitrogen donors such as porphyrin or bidentate ligands of formula (X):

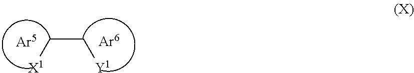

wherein Ar⁵ and Ar⁶ may be the same or different and are independently selected from substituted or unsubstituted aryl or heteroaryl; X¹ and Y¹ may be the same or different and are independently selected from carbon or nitrogen; and Ar⁵ and Ar⁶ may be fused together. Ligands wherein X¹ is carbon and Y¹ is nitrogen are preferred, in particular ligands in which Ar⁵ is a single ring or fused heteroaromatic of N and C atoms only, for example pyridyl or isoquinoline, and Ar⁶ is a single ring or fused aromatic, for example phenyl or naphthyl.

To achieve red emission, Ar⁵ may be selected from phenyl, fluorene, naphthyl and Ar⁶ are selected from quinoline, isoquinoline, thiophene and benzothiophene. Exemplary phosphorescent red emitters include fac-tris(1-phenylisoquinoline)iridium(III), which may be substituted with one or more substituents, for example a substituent R⁵ as described below with reference to formula (V).

To achieve green emission, Ar⁵ may be selected from phenyl or fluorene and Ar⁶ may be pyridine. Exemplary phosphorescent green emitters include fac-tris(2-phenylpyridine)iridium(III), which may be substituted with one or more substituents, for example a substituent R⁵ as described below with reference to formula (V).

Examples of bidentate ligands are illustrated below:

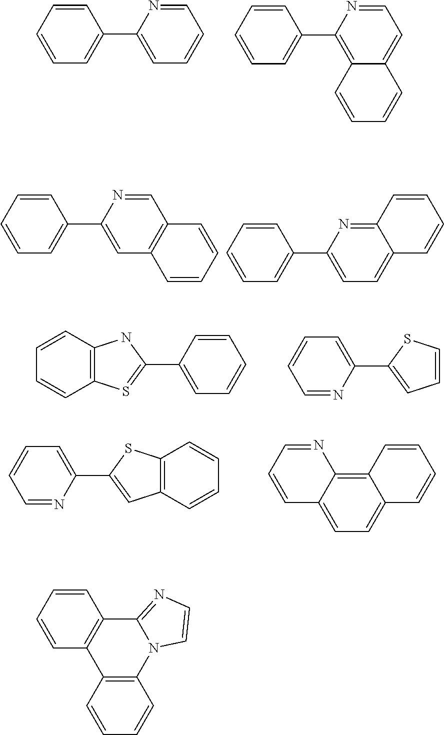

Each of Ar⁵ and Ar⁶ may carry one or more substituents. Two or more of these substituents may be linked to form a ring, for example an aromatic ring.

Other ligands suitable for use with d-block elements include N,N-bidentate ligands, optionally bipyridyl; N,O-bidentate ligands, optionally picolinate; and O,O-bidentate ligands such as diketonates, optionally acac

One or more of L¹, L² and L³ may comprise a carbene group.

Exemplary substituents include groups R⁵ as described below with reference to Formula (V). Particularly preferred substituents include fluorine; trifluoromethyl; C₁₋₂₀ alkyl or alkoxy; carbazole; phenyl or biphenyl which may be unsubstituted or substituted with one or more C₁₋₁₀ alkyl groups; and dendrons.

A light-emitting dendrimer comprises a light-emitting core bound to one or more dendrons, wherein each dendron comprises a branching point and two or more dendritic branches. Preferably, the dendron is at least partially conjugated, and at least one of the branching points and dendritic branches comprises an aryl or heteroaryl group, for example a phenyl group. In one arrangement, the branching point group and the branching groups are all phenyl, and each phenyl may independently be substituted with one or more substituents, for example alkyl or alkoxy.

A dendron may have optionally substituted formula (XI)

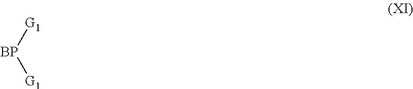

wherein BP represents a branching point for attachment to a core and G₁ represents first generation branching groups.

The dendron may be a first, second, third or higher generation dendron. G₁ may be substituted with two or more second generation branching groups G₂, and so on, as in optionally substituted formula (XIa):

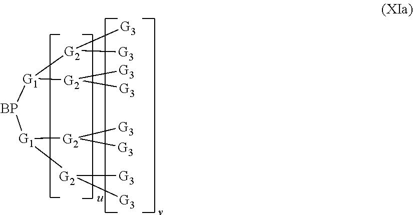

wherein u is 0 or 1; v is 0 if u is 0 or may be 0 or 1 if u is 1; BP represents a branching point for attachment to a core and G₁, G₂ and G₃ represent first, second and third generation dendron branching groups. In one preferred embodiment, each of BP and G₁, G₂ . . . Gₙ is phenyl, and each phenyl BP, G₁, G₂ . . . Gₙ₋₁ is a 3,5-linked phenyl.

A preferred dendron is a substituted or unsubstituted dendron of formula (XIb):

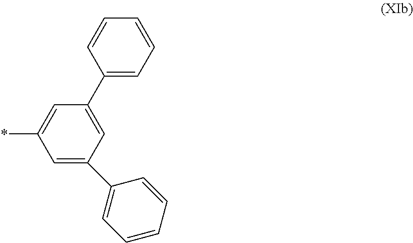 [SMILES: *c1cc(-c2ccccc2)cc(-c2ccccc2)c1]

wherein * represents an attachment point of the dendron to a core.

BP and/or any group G may be substituted with one or more substituents, for example one or more C₁₋₂₀ alkyl or alkoxy groups.

The first, and if present further, phosphorescent light-emitting materials may each independently be admixed with a host material or may be covalently bound to a host material. In the case of a polymeric host, the phosphorescent material(s) may be provided in a side-chain, main chain or end-group of a polymer. Where a phosphorescent material is provided in a polymer side-chain, the phosphorescent material may be directly bound to the backbone of the polymer or spaced apart therefrom by a spacer group, for example a C₁₋₂₀ alkyl spacer group in which one or more non-adjacent C atoms may be replaced by COO, CO, O or S.

Host Materials

The light-emitting layer containing the fluorescent light-emitting material of formula (I) may contain a host material admixed with or bound to the material of formula (I). The host material may have a singlet energy level no more than 0.1 eV lower than that of the fluorescent light-emitting material of formula (I), preferably the same as or higher than the material of formula (I). If this light-emitting layer further contains one or more phosphorescent materials then the triplet energy level of the host may also be no more than 0.1 eV lower than, preferably the same as or higher than, the triplet energy level of the one or more phosphorescent materials.

Devices according to embodiments of the invention may include a light-emitting layer in which the only emissive material or materials are phosphorescent materials. In this case, the triplet energy level of the host may also be no more than 0.1 eV lower than, preferably the same as or higher than, the triplet energy level of the one or more phosphorescent materials.

Host materials include small molecule and polymeric hosts. Polymeric hosts include polymers with a non-conjugated backbone and polymers with an at least partially conjugated backbone. Partially conjugated polymers may contain conjugating repeat units in which the conjugating repeat units provide a conjugation path between the repeat units adjacent to the conjugating repeat units, wherein the extent of conjugation along the polymer backbone is limited, optionally by twisting of the repeat unit by sterically hindering substituents, in order to maintain a relatively high singlet and/or triplet energy level.

Exemplary conjugating repeat units of an at least partially conjugated polymer include arylene or heteroarylene repeat units, for example phenylene repeat units, fluorene repeat units and indenofluorene repeat units. Arylene or heteroarylene repeat units may be unsubstituted or substituted with one or more substituents. A host polymer may include one, two or more different arylene repeat units.

The extent of conjugation that is provided by a conjugating repeat unit may depend on the positions through which the conjugating repeat unit is linked to adjacent repeat units, and may depend on location and nature of substituents on the conjugating repeat unit.

Exemplary fluorene repeat units have formula (V):

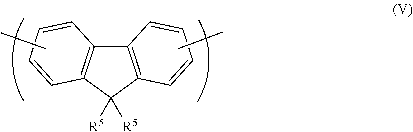

wherein R⁵ in each occurrence is the same or different and is H or a substituent, and wherein the two groups R⁵ may be linked to form a ring.

Each R⁵ is preferably a substituent, and each R⁵ may independently be selected from the group consisting of:
substituted or unsubstituted alkyl, optionally C₁₋₂₀ alkyl, wherein one or more non-adjacent C atoms may be replaced with optionally substituted aryl or heteroaryl, O, S, substituted N, C═O or —COO— and one or more H atoms may be replaced with F;
substituted or unsubstituted aryl or heteroaryl group, or a linear or branched chain of aryl or heteroaryl, each of which may independently be substituted, for example a group of formula —(Ar⁴)ᵣ wherein Ar⁴ in each occurrence independently is a substituted or unsubstituted aryl or heteroaryl and r is at least 1, optionally 1, 2 or 3;
a crosslinkable group attached directly to the fluorene unit or spaced apart therefrom by a spacer group, for example a group comprising a double bond such and a vinyl or acrylate group, or a benzocyclobutane group

In the case where R⁵ comprises one or more aryl or heteroaryl groups Ar⁴, each Ar⁴ may independently be substituted with one or more substituents R⁶ selected from the group consisting of:
alkyl, for example C₁₋₂₀ alkyl, wherein one or more non-adjacent C atoms may be replaced with O, S, substituted N, C═O and —COO— and one or more H atoms of the alkyl group may be replaced with F or aryl or heteroaryl optionally substituted with one or more groups R⁷,
aryl or heteroaryl optionally substituted with one or more groups R⁷, NR⁸₂, OR⁸, SR⁸, and
fluorine, nitro and cyano;

wherein each R⁷ is independently alkyl, for example C₁₋₂₀ alkyl, in which one or more non-adjacent C atoms may be replaced with O, S, substituted N, C═O and —COO— and one or more H atoms of the alkyl group may be replaced with F or D; and each R⁸ is independently selected from the group consisting of alkyl, for example C₁₋₂₀ alkyl, and aryl or heteroaryl optionally substituted with one or more alkyl groups, for example phenyl that is unsubstituted or substituted with one or more C₁₋₂₀ alkyl groups.

Optional substituents for the aromatic carbon atoms of the fluorene unit, i.e. other than substituents R⁵, are preferably selected from the group consisting of alkyl, for example C₁₋₂₀ alkyl, wherein one or more non-adjacent C atoms may be replaced with O, S, NH or substituted N, C═O and —COO—, optionally substituted aryl, optionally substituted heteroaryl, alkoxy, alkylthio, fluorine, cyano and arylalkyl. Particularly preferred substituents include C₁₋₂₀ alkyl and substituted or unsubstituted aryl, for example phenyl. Optional substituents for the aryl include one or more C₁₋₂₀ alkyl groups.

Where present, substituted N may independently in each occurrence be NR⁹ wherein R⁹ is alkyl, optionally C₁₋₂₀ alkyl, or optionally substituted aryl or heteroaryl. Optional substituents for aryl or heteroaryl R⁹ may be selected from R⁷ or R⁸, for example C₁₋₁₀ alkyl.

Preferably, each R⁵ is selected from the group consisting of C₁₋₂₀ alkyl and —(Ar⁴)ᵣ wherein Ar⁴ in each occurrence is substituted or unsubstituted substituted phenyl. Preferred substituents for phenyl are selected from C₁₋₂₀ alkyl groups.

The repeat unit of formula (V) may be a 2,7-linked repeat unit of formula (Va):

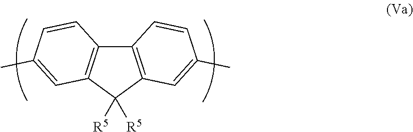

Optionally, the repeat unit of formula (Va) is not substituted in a position adjacent to the 2- or 7-positions.

The extent of conjugation of repeat units of formula (V) to adjacent repeat units may be limited by (a) linking the repeat unit through the 3- and/or 6-positions to limit the extent of conjugation across the repeat unit, and/or (b) substituting the repeat unit with one or more further substituents R⁵ in or more positions adjacent to the linking positions in order to create a twist with the adjacent repeat unit or units, for example a 2,7-linked fluorene carrying a C₁₋₂₀ alkyl sub stituent in one or both of the 3- and 6-positions.

Exemplary conjugating phenylene repeat units have formula (VI):

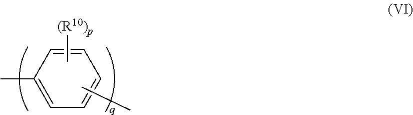

wherein p is 0, 1, 2, 3 or 4, optionally 1 or 2; q is 1, 2 or 3; and R¹⁰ independently in each occurrence is a substituent, optionally a substituent R⁵ as described above with reference to formula (V), for example C₁₋₂₀ alkyl, and phenyl that is unsubstituted or substituted with one or more C₁₋₂₀ alkyl groups.

In the case where q=1, the repeat unit of formula (VI) may be 1,4-linked, 1,2-linked or 1,3-linked.

If the repeat unit of formula (VI) is 1,4-linked and if p is 0 then the extent of conjugation of repeat unit of formula (VI) to one or both adjacent repeat units may be relatively high.

If p is at least 1, and/or the repeat unit is 1,2- or 1,3 linked, then the extent of conjugation of repeat unit of formula (VI) to one or both adjacent repeat units may be relatively low. In one optional arrangement, q=1, the repeat unit of formula (VI) is 1,3-linked and p is 0, 1, 2 or 3. In another optional arrangement, the repeat unit of formula (VI) has formula (VIa):

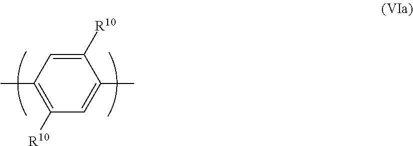

Another exemplary arylene repeat unit has formula (VII):

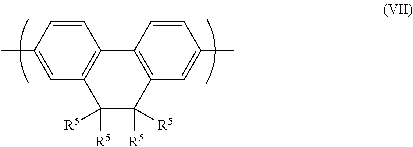

wherein R⁵ is as described with reference to formula (V) above. Each of the R⁵ groups may be linked to any other of the R⁵ groups to form a substituted or unsubstituted ring, for example a ring substituted with one or more C₁₋₂₀ alkyl groups.

Further arylene co-repeat units include: phenanthrene repeat units; naphthalene repeat units; anthracene repeat units; and perylene repeat units. Each of these arylene repeat units may be linked to adjacent repeat units through any two of the aromatic carbon atoms of these units. Specific exemplary linkages include 9,10-anthracene; 2,6-anthracene; 1,4-naphthalene; 2,6-naphthalene; 2,7-phenanthrene; and 2,5-perylene.

The polymer may contain non-conjugating repeat units that block any conjugation path between repeat units adjacent to the non-conjugating repeat unit. Exemplary non-conjugating repeat units have formula (VIII):

—(Ar⁷-Sp¹-Ar⁷)— (VIII)

wherein each Ar⁷ independently represents a substituted or unsubstituted aryl or heteroaryl group; and Sp¹ represents a spacer group that does not provide any conjugation path between the two groups Ar⁷.

Preferably, Ar⁷ is phenyl which may be substituted with one or more substituents R⁵ as described above with respect to formula (V). Preferred substituents are one or more C₁₋₂₀ alkyl groups.

Sp¹ may consist of a group comprising a single non-conjugating atom only between the two groups Ar⁷, or Sp¹ may be a non-conjugating chain comprising at least 2 atoms separating the two groups Ar⁷.

A non-conjugating group may be, for example, —CR¹¹₂— or —SiR¹¹₂— wherein R¹¹ in each occurrence is H or a substituent, optionally C₁₋₂₀ alkyl. Preferably, Sp¹ comprises at least one group of —CR¹¹₂— separating the two groups Ar⁷. Sp1 may be a group of formula —(CR¹¹₂)ᵤ— wherein u is from 1-10 and wherein one or more non-adjacent C atoms may be replaced with O, S, C═O or COO.

Examples of cyclic non-conjugating spacers are optionally substituted cyclohexane or adamantane repeat units that may have the structures illustrated below:

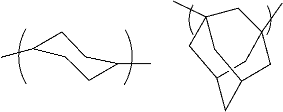

Exemplary substituents for cyclic conjugation repeat units include C₁₋₂₀ alkyl and C₁₋₂₀ alkoxy. Exemplary non-conjugating repeat units include the following:

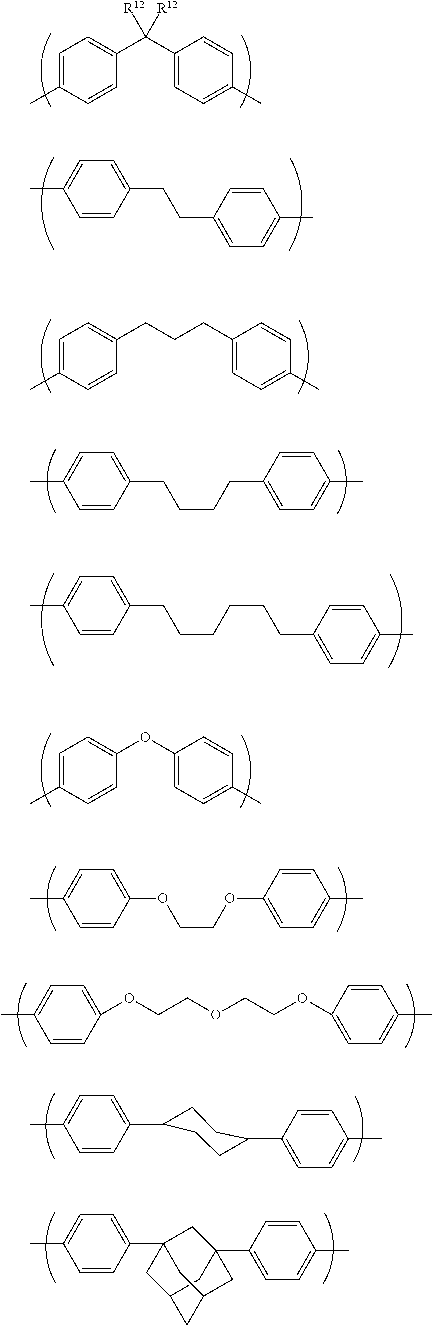

wherein R¹² in each occurrence is independently H or a substituent, optionally H or C₁₋₂₀ alkyl.

The host polymer may be a homopolymer or copolymer comprising a repeat unit of formula (VII):

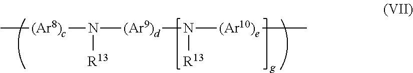

wherein Ar⁸, Ar⁹ and Ar¹⁰ in each occurrence are independently selected from substituted or unsubstituted aryl or heteroaryl, g is 0, 1 or 2, preferably 0 or 1, R¹³ independently in each occurrence is H or a substituent, preferably a substituent, and c, d and e are each independently 1, 2 or 3.

R¹³, which may be the same or different in each occurrence when g is 1 or 2, is preferably selected from the group consisting of alkyl, for example C₁₋₂₀ alkyl, Ar¹¹, a branched or linear chain of Ar¹¹ groups, or a crosslinkable unit that is bound directly to the N atom of formula (I) or spaced apart therefrom by a spacer group, wherein Ar¹¹ in each occurrence is independently optionally substituted aryl or heteroaryl. Exemplary spacer groups are C₁₋₂₀ alkyl, phenyl and phenyl-C₁₋₂₀ alkyl.

Any two aromatic or heteroaromatic groups selected from Ar⁸, Ar⁹, and, if present, Ar¹⁰ and Ar¹¹ directly bound to the same N atom may be linked by a direct bond or a divalent linking atom or group to another of Ar⁸, Ar⁹, Ar¹⁰ and Ar¹¹. Preferred divalent linking atoms and groups include O, S; substituted N; and substituted C.

Ar⁸ is preferably C₆₋₂₀ aryl, more preferably phenyl, that may be unsubstituted or substituted with one or more substituents.

In the case where g=0, Ar⁹ is preferably C₆₋₂₀ aryl, more preferably phenyl, that may be unsubstituted or substituted with one or more substituents.

In the case where g=1, Ar⁹ is preferably C₆₋₂₀ aryl, more preferably phenyl or a polycyclic aromatic group, for example naphthalene, perylene, anthracene or fluorene, that may be unsubstituted or substituted with one or more substituents.

R¹³ is preferably Ar¹¹ or a branched or linear chain of Ar¹¹ groups. Ar¹¹ in each occurrence is preferably phenyl that may be unsubstituted or substituted with one or more substituents.

Exemplary groups R¹³ include the following, each of which may be unsubstituted or substituted with one or more substituents, and wherein * represents a point of attachment to N:

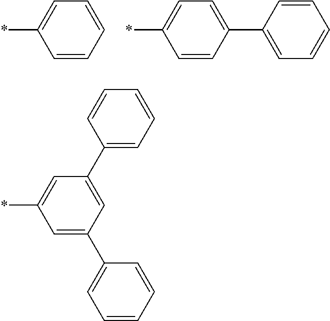

c, d and e are preferably each 1.

Ar⁸, Ar⁹, and, if present, Ar¹⁰ and Ar¹¹ are each independently unsubstituted or substituted with one or more, optionally 1, 2, 3 or 4, substituents. Exemplary substituents may be selected from:
substituted or unsubstituted alkyl, optionally C₁₋₂₀ alkyl, wherein one or more non-adjacent C atoms may be replaced with optionally substituted aryl or heteroaryl (preferably phenyl), O, S, C═O or —COO— and one or more H atoms may be replaced with F; and
a crosslinkable group attached directly to or forming part of Ar⁸, Ar⁹, Ar¹⁰ or Ar¹¹ or spaced apart therefrom by a spacer group, for example a group comprising a double bond such and a vinyl or acrylate group, or a benzocyclobutane group.

Preferred substituents of Ar⁸, Ar⁹, and, if present, Ar¹⁰ and Ar¹¹ are C₁₋₄₀ hydrocarbyl, preferably C₁₋₂₀ alkyl or a hydrocarbyl crosslinking group.

Preferred repeat units of formula (VII) include units of formulae 1-3:

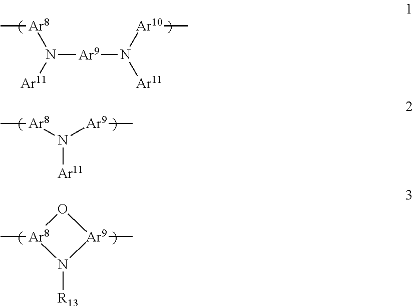

Preferably, Ar⁸, Ar¹⁰ and Ar¹¹ of repeat units of formula 1 are phenyl and Ar⁹ is phenyl or a polycyclic aromatic group.

Preferably, Ar⁸, Ar⁹ and Ar¹¹ of repeat units of formulae 2 and 3 are phenyl.

Preferably, Ar⁸ and Ar⁹ of repeat units of formula 3 are phenyl and R¹¹ is phenyl or a branched or linear chain of phenyl groups.

A polymer comprising repeat units of formula (VII) may be a homopolymer or a copolymer containing repeat units of formula (VII) and one or more co-repeat units.

In the case of a copolymer, repeat units of formula (VII) may be provided in a molar amount in the range of about 1-99 mol %, optionally about 1-50 mol %.

Exemplary co-repeat units include arylene repeat units, optionally arylene units as described above.

The host polymer may contain repeat units of formula (X):

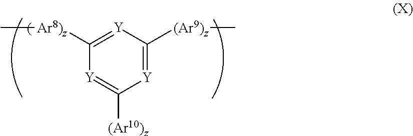

wherein Ar⁸, Ar⁹ and Ar¹⁰ are as described with reference to formula (VII) above, and may each independently be substituted with one or more substituents described with reference to Ar⁸, Ar⁹ and Ar¹⁰, and z in each occurrence is independently at least 1, optionally 1, 2 or 3, preferably 1, and Y is N or CR¹⁴ , wherein R¹⁴ is H or a substituent, preferably H or C₁₋₁₀ alkyl and with the proviso that at least one Y is N. Preferably, Ar⁸, Ar⁹ and Ar¹⁰ of formula (X) are each phenyl, each phenyl being optionally and independently substituted with one or more C₁₋₂₀ alkyl groups.

In one preferred embodiment, all 3 groups Y are N.

Each of Ar⁸, Ar⁹ and Ar¹⁰ may independently be substituted with one or more substituents. Exemplary substituents include R⁵ as described above with reference to formula (V), for example C₁₋₂₀ alkyl or alkoxy.

Ar¹⁰of formula (X) is preferably phenyl, and is optionally substituted with one or more C₁₋₂₀ alkyl groups or a crosslinkable unit. The crosslinkable unit may be bound directly to Ar¹⁰ or spaced apart from Ar¹⁰ by a spacer group.

Preferably, z is 1 and each of Ar⁸, Ar⁹ and Ar¹⁰ is unsubstituted phenyl or phenyl substituted with one or more C₁₋₂₀ alkyl groups.

A particularly preferred repeat unit of formula (X) has formula (Xa), which may be unsubstituted or substituted with or more substituents R⁵, preferably one or more C₁₋₂₀ alkyl groups:

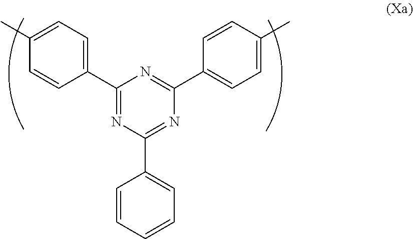

Preferably, polymers comprising repeat units of formula (X) are copolymers comprising one or more arylene repeat units as described above, and one or more repeat units of formula (X).

Polymer Synthesis

Preferred methods for preparation of conjugated polymers, such as host polymers or charge transporting polymers for use in a charge transporting layer, comprise a “metal insertion” wherein the metal atom of a metal complex catalyst is inserted between an aryl or heteroaryl group and a leaving group of a monomer. Exemplary metal insertion methods are Suzuki polymerisation as described in, for example, WO 00/53656 and Yamamoto polymerisation as described in, for example, T. Yamamoto, “Electrically Conducting And Thermally Stable pi-Conjugated Poly(arylene)s Prepared by Organometallic Processes”, Progress in Polymer Science 1993, 17, 1153-1205. In the case of Yamamoto polymerisation, a nickel complex catalyst is used; in the case of Suzuki polymerisation, a palladium complex catalyst is used.

For example, in the synthesis of a linear polymer by Yamamoto polymerisation, a monomer having two reactive halogen groups is used. Similarly, according to the method of Suzuki polymerisation, at least one reactive group is a boron derivative group such as a boronic acid or boronic ester and the other reactive group is a halogen. Preferred halogens are chlorine, bromine and iodine, most preferably bromine.

It will therefore be appreciated that repeat units illustrated throughout this application may be derived from a monomer carrying suitable leaving groups Likewise, an end-capping group or side group carrying only one reactive leaving group may be bound to the polymer by reaction of a leaving group at the polymer chain end or side respectively.

Suzuki polymerisation may be used to prepare regioregular, block and random copolymers. In particular, homopolymers or random copolymers may be prepared when one reactive group is a halogen and the other reactive group is a boron derivative group. Alternatively, block or regioregular copolymers may be prepared when both reactive groups of a first monomer are boron and both reactive groups of a second monomer are halogen.

As alternatives to halides, other leaving groups capable of participating in metal insertion include sulfonic acids and sulfonic acid esters such as tosylate, mesylate and triflate.

Charge Transporting and Charge Blocking Layers

A device containing a light-emitting layer containing a compound of formula (I) may have charge-transporting and/or charge blocking layers.

A hole transporting layer may be provided between the anode and the light-emitting layer or layers of an OLED. An electron transporting layer may be provided between the cathode and the light-emitting layer or layers.

An electron blocking layer may be provided between the anode and the light-emitting layer(s) and a hole blocking layer may be provided between the cathode and the light-emitting layer(s). Charge-transporting and charge-blocking layers may be used in combination. Depending on the HOMO and LUMO levels of the material or materials in a layer, a single layer may both transport one of holes and electrons and block the other of holes and electrons.

If present, a hole transporting layer located between the anode and the light-emitting layer(s) preferably has a material having a HOMO level of less than or equal to 5.5 eV, more preferably around 4.8-5.5 eV or 4.9-5.3 eV as measured by cyclic voltammetry. The HOMO level of the material in the hole transport layer may be selected so as to be within 0.2 eV, optionally within 0.1 eV of the light-emitting material of the light-emitting layer.

A hole-transporting layer may contain polymeric or non-polymeric charge-transporting materials. Exemplary hole-transporting materials contain arylamine groups.

A hole transporting layer may contain a homopolymer or copolymer comprising a repeat unit of formula (VII) as described above.

If present, an electron transporting layer located between the light-emitting layers and cathode preferably has a LUMO level of around 1.8-2.7 eV as measured by cyclic voltammetry. An electron-transporting layer may have a thickness in the range of about 5-50 nm.

A charge-transporting layer or charge-blocking layer may be crosslinked, particularly if a layer overlying that charge-transporting or charge-blocking layer is deposited from a solution. The crosslinkable group used for this crosslinking may be a crosslinkable group comprising a reactive double bond such and a vinyl or acrylate group, or a benzocyclobutane group. The crosslinkable group may be provided as a substituent of, or may be mixed with, a charge-transporting or charge-blocking material used to form the charge-transporting or charge-blocking layer.

A charge-transporting layer adjacent to a light-emitting layer containing a phosphorescent light-emitting material preferably contains a charge-transporting material having a lowest triplet excited state (T₁) excited state that is no more than 0.1 eV lower than, preferably the same as or higher than, the T₁ excited state energy level of the phosphorescent light-emitting material(s) in order to avoid quenching of triplet excitons.

A charge-transporting layer as described herein may be non-emissive, or may contain a light-emitting material such that the layer is a charge transporting light-emitting layer. If the charge-transporting layer is a polymer then a light-emitting dopant may be provided as a side-group of the polymer, a repeat unit in a backbone of the polymer, or an end group of the polymer. Optionally, a hole-transporting polymer as described herein comprises a phosphorescent polymer in a side-group of the polymer, in a repeat unit in a backbone of the polymer, or as an end group of the polymer.

The polystyrene-equivalent number-average molecular weight (Mn) measured by gel permeation chromatography of the polymers described herein may be in the range of about 1×10³ to 1×10⁸, and preferably 1×10⁴ to 5×10⁶. The polystyrene-equivalent weight-average molecular weight (Mw) of the polymers described herein may be 1×10³ to 1×10⁸, and preferably 1×10⁴ to 1×10⁷.

Polymers as described herein are suitably amorphous.

Hole Injection Layers

A conductive hole injection layer, which may be formed from a conductive organic or inorganic material, may be provided between the anode 101 and the light-emitting layer 103 of an OLED as illustrated in FIG. 1 to assist hole injection from the anode into the layer or layers of semiconducting polymer. Examples of doped organic hole injection materials include optionally substituted, doped poly(ethylene dioxythiophene) (PEDOT), in particular PEDOT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and optionally substituted polythiophene or poly(thienothiophene). Examples of conductive inorganic materials include transition metal oxides such as VOx, MoOx and RuOx as disclosed in Journal of Physics D: Applied Physics (1996), 29(11), 2750-2753.

Cathode

The cathode 105 is selected from materials that have a workfunction allowing injection of electrons into the light-emitting layer of the OLED. Other factors influence the selection of the cathode such as the possibility of adverse interactions between the cathode and the light-emitting material. The cathode may consist of a single material such as a layer of aluminium. Alternatively, it may comprise a plurality of conductive materials such as metals, for example a bilayer of a low workfunction material and a high workfunction material such as calcium and aluminium, for exampleas disclosed in WO 98/10621. The cathode may comprise elemental barium, for example as disclosed in WO 98/57381, Appl. Phys. Lett. 2002, 81(4), 634 and WO 02/84759. The cathode may comprise a thin (e.g. 1-5 nm) layer of metal compound, in particular an oxide or fluoride of an alkali or alkali earth metal, between the organic layers of the device and one or more conductive cathode layers to assist electron injection, for example lithium fluoride as disclosed in WO 00/48258; barium fluoride as disclosed in Appl. Phys. Lett. 2001, 79(5), 2001; and barium oxide. In order to provide efficient injection of electrons into the device, the cathode preferably has a workfunction of less than 3.5 eV, more preferably less than 3.2 eV, most preferably less than 3 eV. Work functions of metals can be found in, for example, Michaelson, J. Appl. Phys. 48(11), 4729, 1977.

The cathode may be opaque or transparent. Transparent cathodes are particularly advantageous for active matrix devices because emission through a transparent anode in such devices is at least partially blocked by drive circuitry located underneath the emissive pixels. A transparent cathode comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

Encapsulation

Organic optoelectronic devices tend to be sensitive to moisture and oxygen. Accordingly, the substrate preferably has good barrier properties for prevention of ingress of moisture and oxygen into the device. The substrate is commonly glass, however alternative substrates may be used, in particular where flexibility of the device is desirable. For example, the substrate may comprise one or more plastic layers, for example a substrate of alternating plastic and dielectric barrier layers or a laminate of thin glass and plastic.

The device may be encapsulated with an encapsulant (not shown) to prevent ingress of moisture and oxygen. Suitable encapsulants include a sheet of glass, films having suitable barrier properties such as silicon dioxide, silicon monoxide, silicon nitride or alternating stacks of polymer and dielectric or an airtight container. In the case of a transparent cathode device, a transparent encapsulating layer such as silicon monoxide or silicon dioxide may be deposited to micron levels of thickness, although in one preferred embodiment the thickness of such a layer is in the range of 20-300 nm. A getter material for absorption of any atmospheric moisture and/or oxygen that may permeate through the substrate or encapsulant may be disposed between the substrate and the encapsulant.

Formulation Processing

A formulation suitable for forming a light-emitting layer may be formed from a compound of formula (I) and any further components of the layer such as light-emitting materials, and one or more suitable solvents.

The formulation may be a solution of the compound of formula (I) and any other components in the one or more solvents, or may be a dispersion in the one or more solvents in which one or more components are not dissolved. Preferably, the formulation is a solution.

Solvents suitable for dissolving compounds of formula (I) are solvents comprising alkyl substituents for example benzenes substituted with one or more C₁₋₁₀ alkyl or C₁₋₁₀ alkoxy groups, for example toluene, xylenes and methylanisoles.

Particularly preferred solution deposition techniques including printing and coating techniques such spin-coating, inkjet printing and slot-die coating.

Spin-coating is particularly suitable for devices wherein patterning of the light-emitting layer is unnecessary—for example for lighting applications or simple monochrome segmented displays.

Inkjet printing is particularly suitable for high information content displays, in particular full colour displays. A device may be inkjet printed by providing a patterned layer over the first electrode and defining wells for printing of one colour (in the case of a monochrome device) or multiple colours (in the case of a multicolour, in particular full colour device). The patterned layer is typically a layer of photoresist that is patterned to define wells as described in, for example, EP 0880303.

As an alternative to wells, the ink may be printed into channels defined within a patterned layer. In particular, the photoresist may be patterned to form channels which, unlike wells, extend over a plurality of pixels and which may be closed or open at the channel ends.

Other solution deposition techniques include dip-coating, roll printing and screen printing.

### EXAMPLES

Light-Emitting Formulations 1-3

Fluorescent Compound 1 was prepared as disclosed in Thiessen et al, Organic Electronics 13 (2012) 71-83, the contents of which are incorporated herein by reference.

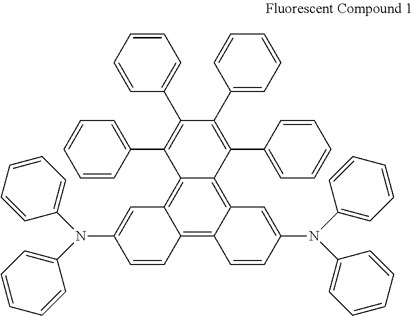 [SMILES: c1ccc(-c2c(-c3ccccc3)c(-c3ccccc3)c3c4cc(N(c5ccccc5)c5ccccc5)ccc4c4ccc(N(c5ccccc5)c5ccccc5)cc4c3c2-c2ccccc2)cc1]

Fluorescent Compound 1 has a T1 energy level of 2.43 eV as measured by low temperature phosphorescence spectroscopy.

Solutions for forming a light-emitting composition were formed by dissolving Host Polymer 1, Fluorescent Compound 1, Green Phosphorescent Compound 1 and Red Phosphorescent Compound 1 in ortho-xylene in the amounts given in Table 1

| | Formulation 1 | Formulation 2 | Formulation 3 |
|---|---|---|---|
| Compound | (mol %) | (mol %) | (mol %) |
| Fluorescent | 4 | 4 | 4 |
| Compound 1 | | | |
| Green Phosphorescent | 0.5 | 0.5 | 1 |
| Compound 1 | | | |
| Red Phosphorescent | 0.24 | 0.36 | 0.5 |
| Compound 1 | | | |
| Host Polymer 1 | 95.26 | 95.14 | 94.5 |

Green Phosphorescent Compound 1, T₁ 2.41-2.43 eV 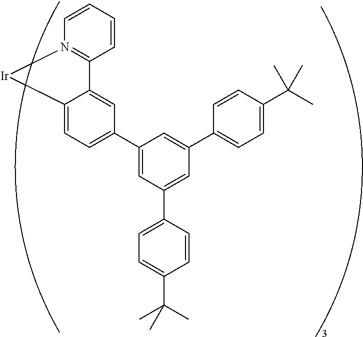
Red Phosphorescent Compound 1, T₁ = 2.20 eV

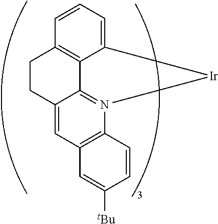

Host Polymer 1 was formed by Suzuki polymerisation as described in WO 00/53656 of the following monomers:

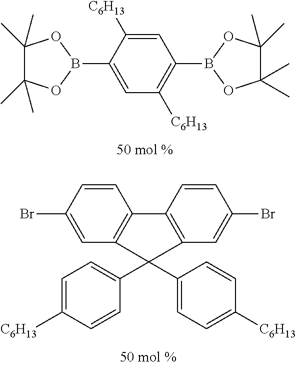

Host Polymer 1 has a T₁ of 2.48 eV.

### Device Example 1

An organic light-emitting device having the following structure was prepared:

ITO/HIL/HTL/LE/ETL/Cathode

wherein ITO is an indium-tin oxide anode; HIL is a hole-injecting layer comprising a hole-injecting material, HTL is a hole-transporting layer, LE is a light-emitting layer.

A substrate carrying ITO (35 nm) was cleaned using UV/Ozone. The hole injection layer was formed by spin-coating an aqueous formulation of a hole-injection material available from Plextronics, Inc. A hole transporting layer was formed to a thickness of 22 nm by spin-coating a hole-transporting polymer from o-xylene solution and crosslinking the polymer by heating. A light-emitting layer was formed by depositing Light-Emitting Formulation 1 to a thickness of 70 nm by spin-coating. An electron-transporting layer was formed by spin-coating an electron-transporting polymer as described in WO 2012/133229 from methanol. A cathode was formed by evaporation of a first layer of sodium fluoride to a thickness of about 2 nm, a second layer of aluminium to a thickness of about 100 nm and a third layer of silver to a thickness of about 100 nm.

The hole-transporting polymer was formed by Suzuki polymerization as described in WO 00/53656 of the following monomers:

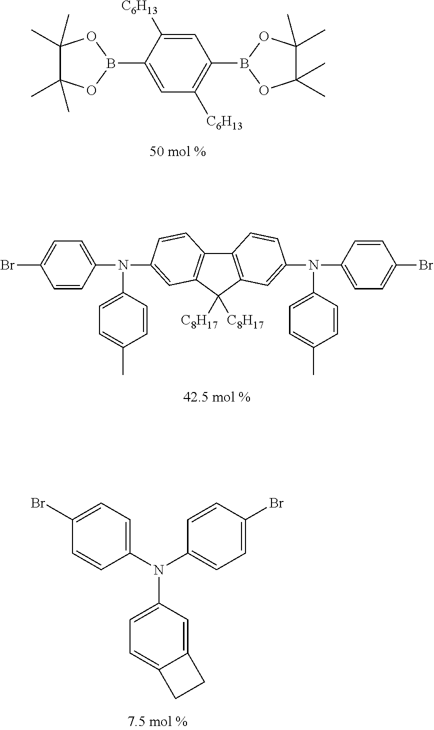

The hole-transporting polymer has a T₁ of 2.37eV

### Device Example 2

An organic light-emitting device was prepared as described in Device Example 1 except that Light-Emitting Formulation 2 was used in place of Light-Emitting Composition 1.

### Device Example 3

An organic light-emitting device was prepared as described in Device Example 1 except that Light-Emitting Formulation 3 was used in place of Light-Emitting Composition 1.

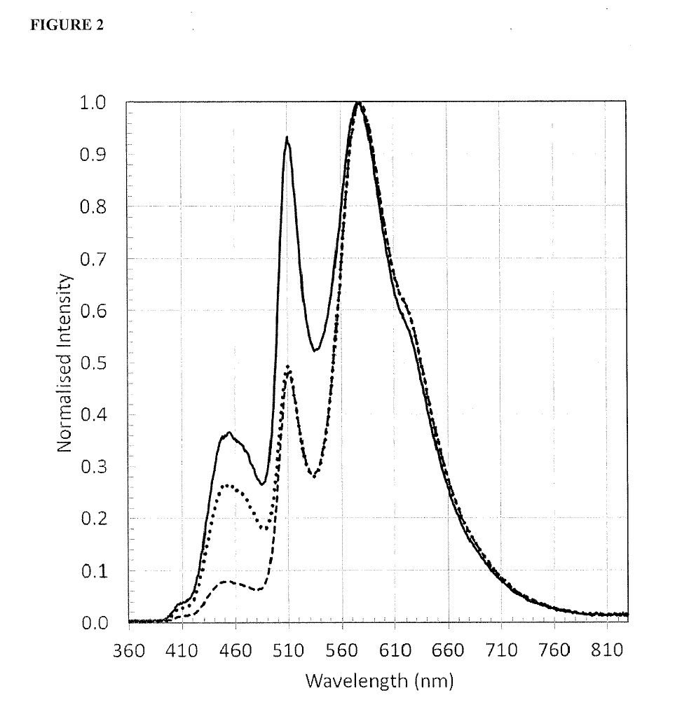

FIG. 2 illustrates the electroluminescence spectra of Device Examples 1-3 normalized to red emission wherein Device Example 1 is the solid line, Device Example 2 is the dotted line and Device Example 3 is the dashed line.

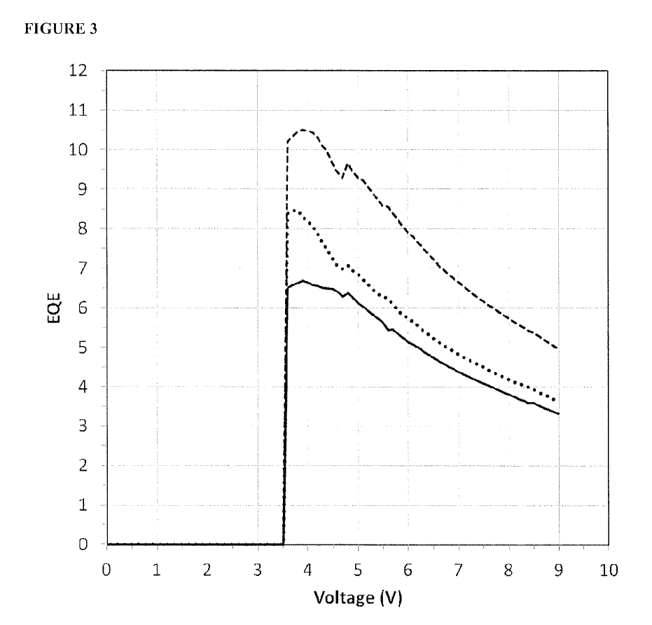

FIG. 3 illustrates the external quantum efficiencies vs voltage of Device Examples 1-3

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. An organic light-emitting device comprising an anode; a cathode; and a first light-emitting layer between the anode and the cathode, wherein the first light-emitting layer comprises a fluorescent light-emitting material of formula (I): 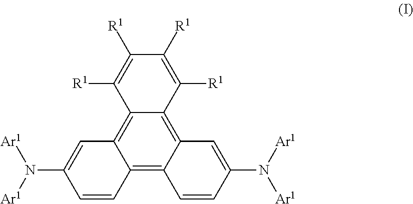
wherein Ar¹ independently in each occurrence is a substituted or unsubstituted aryl or heteroaryl group and each R¹ is independently H or a substituent; and
wherein a first phosphorescent light-emitting material is provided in the first light-emitting layer or in a second light-emitting layer adjacent to the first light-emitting layer.

2. An organic light-emitting device according to claim 1 wherein each Ar¹ is an aryl group.

3. An organic light-emitting device according to claim 2 wherein Ar¹ is phenyl.

4. An organic light-emitting device according to claim 1 wherein each R¹ is a substituted or unsubstituted aryl or heteroaryl.

5. An organic light-emitting device according to claim 4 wherein each R¹ is a substituted or unsubstituted phenyl.

6. An organic light-emitting device according to claim 1 wherein the fluorescent light-emitting material has a photoluminescent peak of less than 490 nm.

7. An organic light-emitting device according to claim 1 where the first phosphorescent light-emitting material has a photoluminescent peak in the range of 490-580 nm.

8. An organic light-emitting device according to claim 1 wherein the first phosphorescent light-emitting material is a metal complex.

9. An organic light-emitting device according to claim 1 wherein the first light-emitting layer further comprises a host material.

10. An organic light-emitting device according to claim 9 wherein the host material is a polymer.

11. An organic light-emitting device according to claim 1 wherein the first phosphorescent light-emitting material is provided in the first light-emitting layer

12. An organic light-emitting device according to claim 11 wherein substantially all light emitted from the device is emitted from the first light-emitting layer.

13. An organic light-emitting device according to claim 1 wherein the first phosphorescent light-emitting material is provided in a second light-emitting layer adjacent to the first light-emitting layer.

14. An organic light-emitting device according to claim 1 wherein the device comprises a second phosphorescent light-emitting material in a light-emitting layer of the device.

15. An organic light-emitting device according to claim 14 wherein the second phosphorescent light-emitting material has a photoluminescent peak of greater than 580 nm.

16. An organic light-emitting device according to claim 1 wherein the device emits white light.

17. A light-emitting composition comprising a fluorescent light-emitting material of formula (I) and a first phosphorescent light-emitting material: 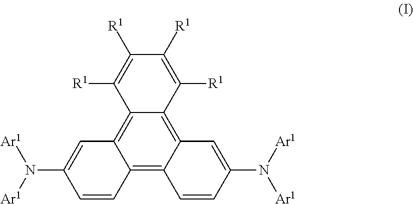
wherein Ar¹ independently in each occurrence is a substituted or unsubstituted aryl or heteroaryl group and each R¹ is independently H or a substituent.

18. A formulation comprising a composition according to claim 17 and at least one solvent.

19. A method of forming an OLED according to claim 1, the method comprising the steps of forming the first and, if present, the second light-emitting layer over the anode; and forming a cathode over the first and second light-emitting layers, wherein the light-emitting layers may be deposited in any order in the case where the second light-emitting layer is present.

20. A method according to claim 19 wherein each of the first light-emitting layer and, if present, the second light-emitting layer are formed by depositing, respectively, a first solution comprising the fluorescent light-emitting material and at least one solvent followed by evaporation of the at least one solvent and a second solution comprising the phosphorescent light-emitting material and at least one solvent followed by evaporation of the at least one solvent.
